(19) United States
(12) Patent Application Publication
(10) Pub. No.: US 2026/0231821 A1
(43) Pub. Date: Aug. 6, 2026

(54) THREE-DIMENSIONAL SEMICONDUCTOR INTEGRATED CIRCUIT WITH INTER-DIE CONNECTIONS AND METHOD FOR MANUFACTURING THE SAME

(71) Applicant: EINSNEXT PTE. LTD., Singapore (SG)

(72) Inventors: Yantao Jia, Stow, MA (US); Ming-Te Hung, Hsinchu County (TW); Tsung YU CHEN, Hsinchu County (TW)

(21) Appl. No.: 19/045,584

(22) Filed: Feb. 5, 2025

(51) Int. Cl. H10W 90/00; H10W 80/00; H10W 90/20; H10W 90/22

(52) U.S. Cl. CPC H10W 90/00; H10W 80/312; H10W 90/22; H10W 90/297; H10W 90/792

(57) ABSTRACT

There is provided a 3D semiconductor integrated circuit including a system-on-chip (SoC) wafer and a companion wafer. The SoC wafer includes multiple SoC dies. The companion wafer includes multiple companion dies with inter-die connections between adjacent companion dies. The SoC wafer is bonded onto the companion wafer to cause the multiple SoC dies to communicate to adjacent SoC dies via the inter-die connections on the companion wafer.

### FIELD OF THE DISCLOSURE

This disclosure generally relates to a three-dimensional semiconductor integrated circuit and, more particularly, to a three-dimensional multi-layer wafer with inter-die connections for Wafer-on-Wafer (WoW) and a method for manufacturing the same.

### BACKGROUND OF THE DISCLOSURE

The artificial intelligence requires extremely large data sets in training algorithms, but the underlying computer architecture is not sufficient enough for the artificial intelligence training.

It is known that a three-dimensional system-on-chip (3D SoC) can meet the requirements of high integration and speed. The present disclosure provides a 3D semiconductor integrated circuit that fulfills the requirement of dealing with large data sets in artificial intelligence training.

The information disclosed in this BACKGROUND is merely intended to increase understanding of the general background of the invention and should not be taken as an admission or in any way implied that the relevant information constitutes prior art that is already known to a person of ordinary skill in the art.

### SUMMARY

Accordingly, the present disclosure provides a 3D semiconductor integrated circuit in which the inter-die communication between SoC dies of an SoC wafer is implemented through inter-die connections between companion dies on a companion wafer, and a method of manufacturing the 3D semiconductor integrated circuit.

The present disclosure provides a 3D semiconductor integrated circuit including two SoC dies and two companion dies. The two SoC dies are adjacent to each other. The two companion dies are adjacent to each other and provide with at least one inter-die connection therebetween. Each of the two SoC dies is bonded to each of the two companion dies through hybrid bond to cause one of the two SoC dies to communicate with the other one of the two SoC dies through the hybrid bond and the at least one inter-die connection.

The present disclosure further provides a 3D semiconductor integrated circuit including an SoC wafer and a companion wafer. The SoC wafer includes multiple SoC dies. The companion wafer includes multiple companion dies with inter-die connections between the multiple companion dies. The companion wafer is bonded onto the SoC wafer to cause adjacent SoC dies of the SoC wafer to be electrically coupled to each other via the inter-die connections on the companion wafer.

The present disclosure further provides a method of manufacturing a 3D semiconductor integrated circuit, including the steps of: providing an SoC wafer having multiple SoC dies; providing a companion wafer having multiple companion dies and inter-die connections between the multiple companion dies; and bonding the companion wafer onto the SoC wafer to cause one SoC die on the SoC wafer to electrically coupled to an adjacent SoC die via the inter-die connections on the companion wafer.

In the present disclosure, an inter-die communication between two SoC dies is implemented by hybrid bond extending from the SoC dies to the companion dies as well as a transverse inter-die connection between two companion dies.

### BRIEF DESCRIPTION OF DRAWINGS

Other objects, advantages, and novel features of the present disclosure will become more apparent from the following detailed description when taken in conjunction with the accompanying drawings.

FIG. 1 is a plane view of two SoC dies according to one embodiment of the present disclosure.

FIG. 2 is a cross sectional view of the SoC dies along line 2-2’ in FIG. 1 according to one embodiment of the present disclosure.

FIG. 3 is a plane view of two companion dies according to one embodiment of the present disclosure.

FIGS. 3A-3C are schematic diagrams of steps for manufacturing companion dies in FIG. 3.

FIGS. 4A-4B are cross sectional views of the companion dies along line 4-4’ in FIG. 3 according to some embodiments of the present disclosure.

FIG. 5 is a cross sectional view of a 3D semiconductor integrated circuit according to one embodiment of the present disclosure.

FIG. 6 is a flow chat of a method for manufacturing a 3D semiconductor integrated circuit according to one embodiment of the present disclosure.

FIG. 7 is a schematic diagram of an SoC wafer according to one embodiment of the present disclosure.

FIG. 8 is a schematic diagram of a companion wafer according to one embodiment of the present disclosure.

### DETAILED DESCRIPTION OF THE DISCLOSURE

It should be noted that, wherever possible, the same reference numbers will be used throughout the drawings to refer to the same or like parts.

One objective of the present disclosure is to provide a three-dimensional (3D) semiconductor integrated circuit including a companion wafer stacked on a system-on-chip (SoC) wafer to form so-called wafer-on-wafer structure. The companion wafer includes multiple companion dies with inter-die connections, which are used to provide inter-die communication between SoC dies of the SoC wafer. That is, the inter-die communication of the SoC wafer is implemented by the inter-die connections of a different wafer stacked thereon and bonded thereto.

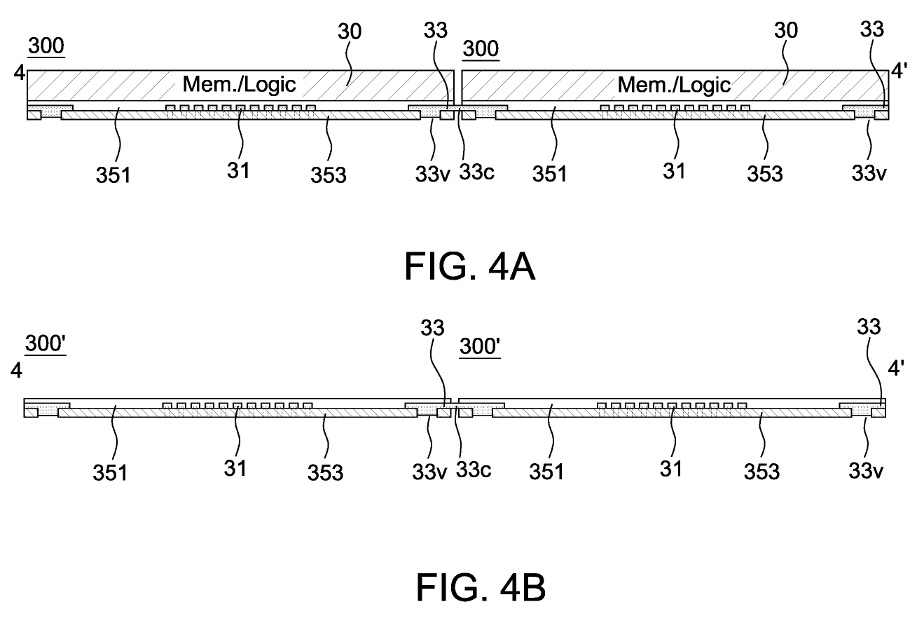

The companion wafer herein includes, for example, a memory wafer and a logic wafer, shown as Mem./Logic, in FIG. 4A, an interposer shown in FIG. 4B, and other wafers adapted to multi-level wafers.

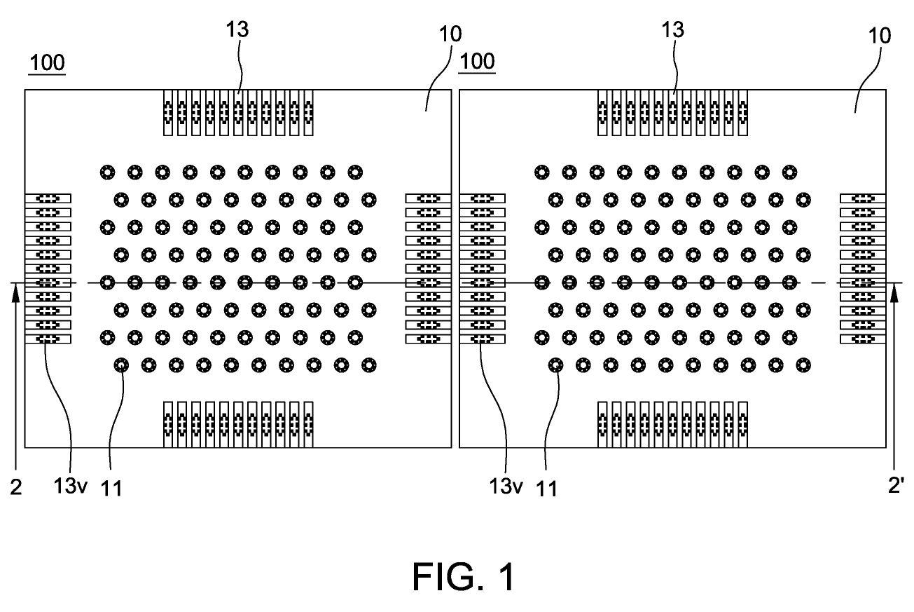

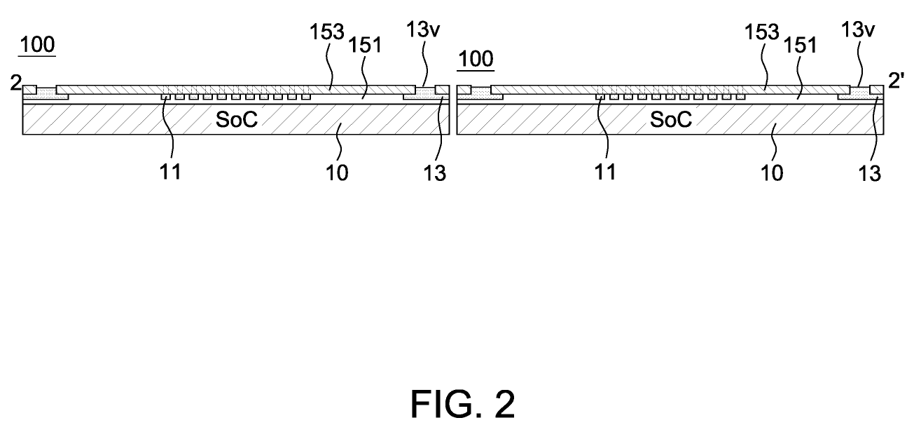

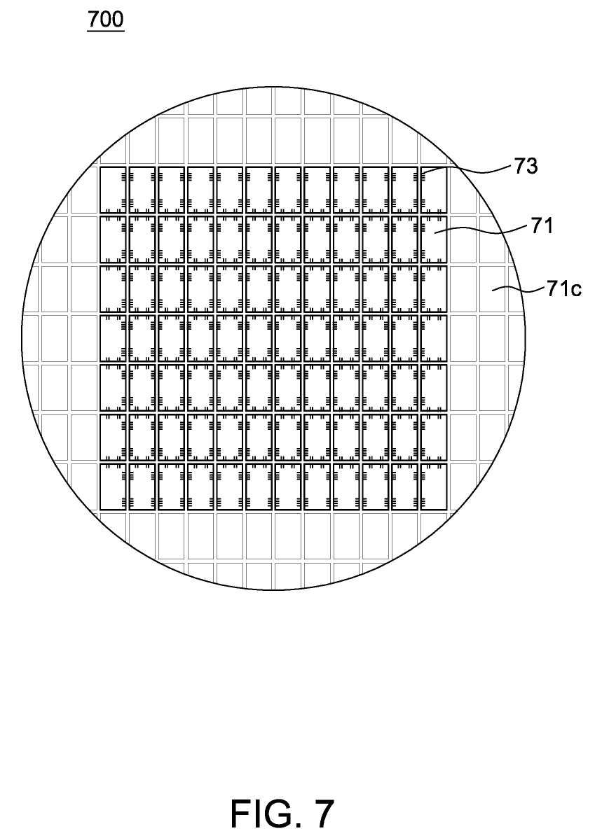

Please refer to FIGS. 1-2, FIG. 1 is a plane view of two SoC dies (e.g., logic dies, but not limited thereto) 100 according to one embodiment of the present disclosure; and FIG. 2 is a cross sectional view of the SoC dies 100 along line 2-2’ in FIG. 1 according to one embodiment of the present disclosure. It should be mentioned that although FIGS. 1-2 use two adjacent SoC dies 100 as an example for illustration, it is only intended to illustrate but not to limit the present disclosure. An SoC wafer may include multiple SoC dies, e.g., as shown in FIG. 7.

Each SoC die 100 includes a circuit layer (or called substrate) 10, a first non-conductive layer 151, multiple bond pads 11, a first redistribution layer (RDL) 13 and a second non-conductive layer 153. The material of the first non-conductive layer 151 and the second non-conductive layer 153 are not particularly limited as long as they can electrically isolate components therein. The method of forming a non-conductive layer on a substrate is known to the art and not a main objective of the present disclosure, and thus details thereof are not described herein.

The circuit layer 10 includes microelectronic devices (not shown) therein such as transistors, diodes and various circuits for performing predetermined functions thereof, and the microelectronic devices are formed by photolithographic processes, which are known to the art and thus details thereof are not described herein.

The multiple bond pads 11 are for hybrid bonding to electrically couple the circuit layer 10 to external devices or components, e.g., to a corresponding companion die 300 mentioned below.

The first redistribution layer 13 includes at least one conductive wire (multiple wires being shown at four edges of each SoC die 100). In one aspect, the at least one conductive wire extends perpendicularly to edges of the SoC die 100. The first redistribution layer 13 is electrically connected to SoC circuits in the circuit layer 10, e.g., connecting to a transmitting circuit and a receiving circuit of an SoC die 100 in order to send out and receive communication signals.

The second non-conductive layer 153 covers on the first redistribution layer 13 and the first non-conductive layer 151, and is formed with at least one bond 13v corresponding to each conductive wire to expose a part of each conductive wire for electrical connection with a companion die.

In the present disclosure, numbers of the conductive wires and the bonds 13v are determined according to communication requirement, e.g., bandwidth and connectivity, between the SoC dies 100.

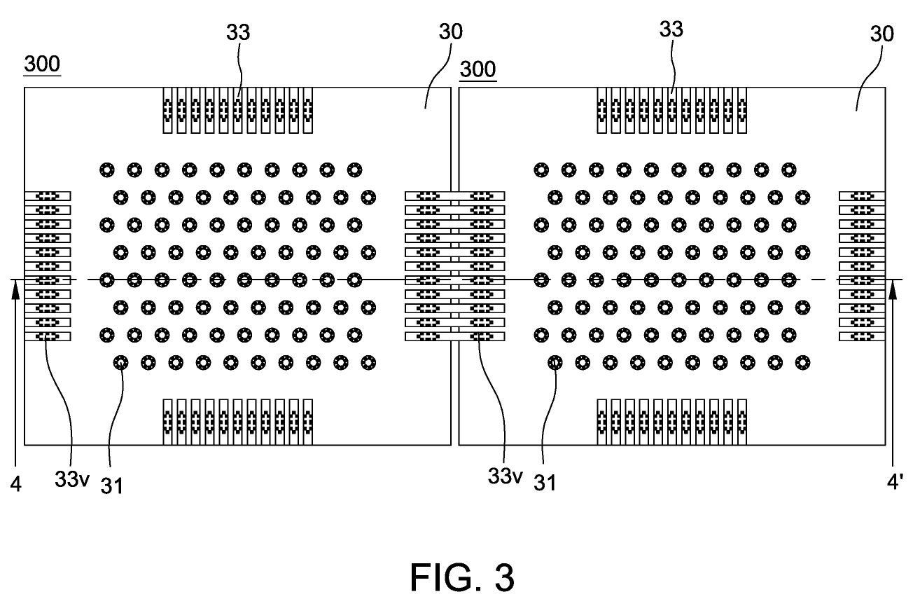

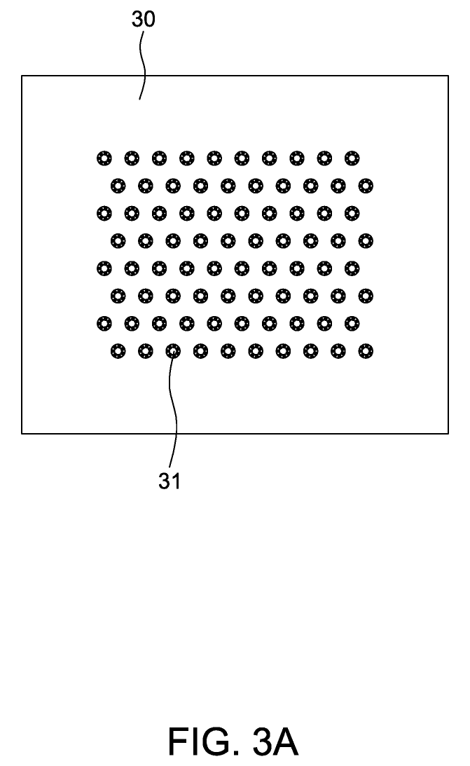

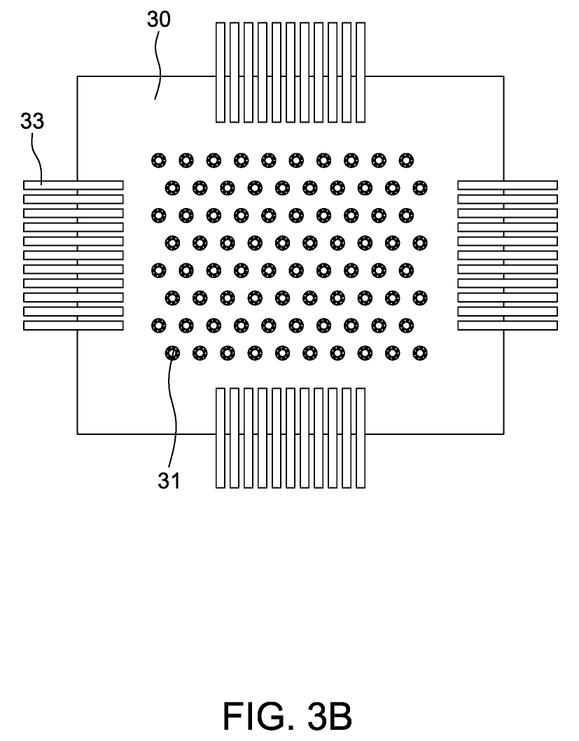

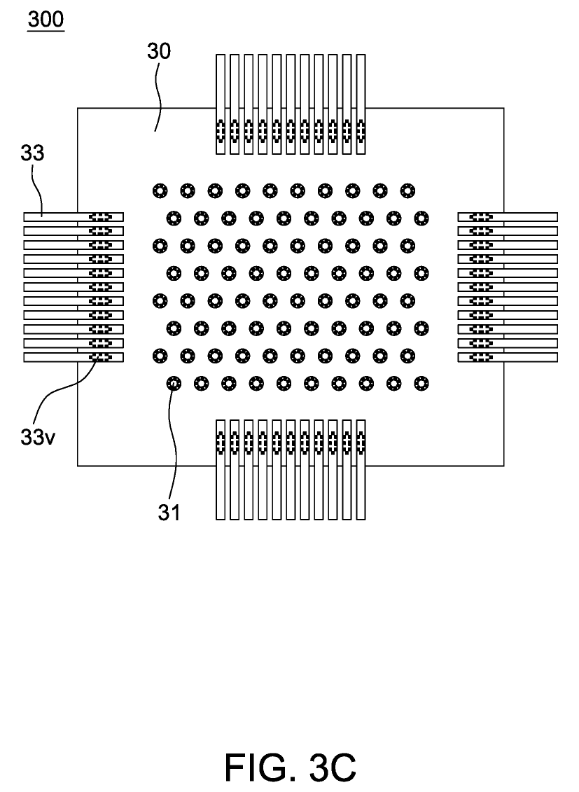

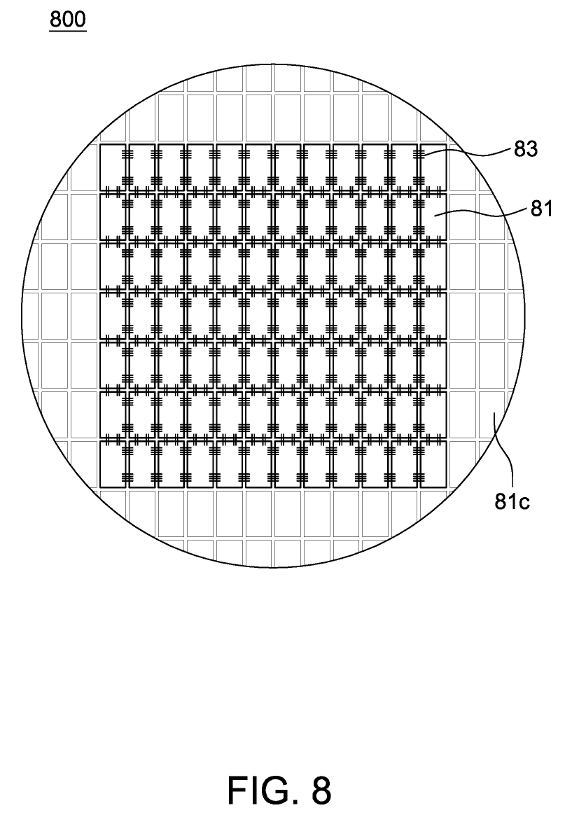

Please refer to FIGS. 3 and 4A-4B, FIG. 3 is a plane view of two companion dies 300 according to one embodiment of the present disclosure; and FIGS. 4A-4B are cross sectional views of the companion dies (including memory/logic dies 300 in FIG. 4A and interposer 300’ in FIG. 4B) along line 4-4’ in FIG. 3 according to some embodiments of the present disclosure. It should be mentioned that although FIGS. 3 and 4A-4B use two adjacent companion dies 300 as an example for illustration, it is only intended to illustrate but not to limit the present disclosure. A companion wafer may include multiple companion dies, e.g., as shown in FIG. 8. It is appreciated that a top surface in FIG. 3 is faced downward in FIGS. 4A-4B for illustration purposes.

Each companion die 300 includes a circuit layer (or called substrate) 30, a first non-conductive layer 351, multiple bond pads 31, a second redistribution layer 33 and a second non-conductive layer 353. Similarly, the material of the first non-conductive layer 351 and the second non-conductive layer 353 are not particularly limited as long as they can electrically isolate components therein.

The circuit layer 30 includes circuits such as transistors, diodes and various circuits formed by photolithographic processes having predetermined functions.

The multiple bond pads 31 are for hybrid bonding to electrically couple the circuit layer 30 to external devices or components, e.g., to a corresponding SoC die 100.

The second redistribution layer 33 includes at least one conductive wire (multiple wires being shown at four edges of each companion die 300). In one aspect, the at least one conductive wire extends perpendicularly out of edges of the companion die 300 and connects to adjacent companion dies. That is, two adjacent companion dies 300 are connected by at least one inter-die connection (i.e. conductive wire) 33c therebetween, and each of the two adjacent companion dies 300 includes a second redistribution layer 33 to form the at least one inter-die connection 33c. In one aspect, the inter-die connections 33c are arranged perpendicular to edges of the multiple companion dies 300. The inter-die RDLs 33 are used to connect adjacent companion dies, but are not connected to any circuit inside the companion dies.

It should be mentioned that although FIG. 3 shows that only the conductive wires between adjacent companion dies 300 form inter-die connections, and the conductive wires at other edges (not between dies) of the companion dies 300 do not extend out of the edges, it is only intended to illustrate but not to limit the present disclosure. In another aspect, edges between two companion dies 300 may not arranged with any conductive wire if no inter-die communication is required between the two companion dies 300.

The second non-conductive layer 353 covers on the second redistribution layer 33 and the first non-conductive layer 351, and is formed with at least one bond 33v corresponding to each conductive wire to expose a part of each conductive wire for electrical connection with an SoC die.

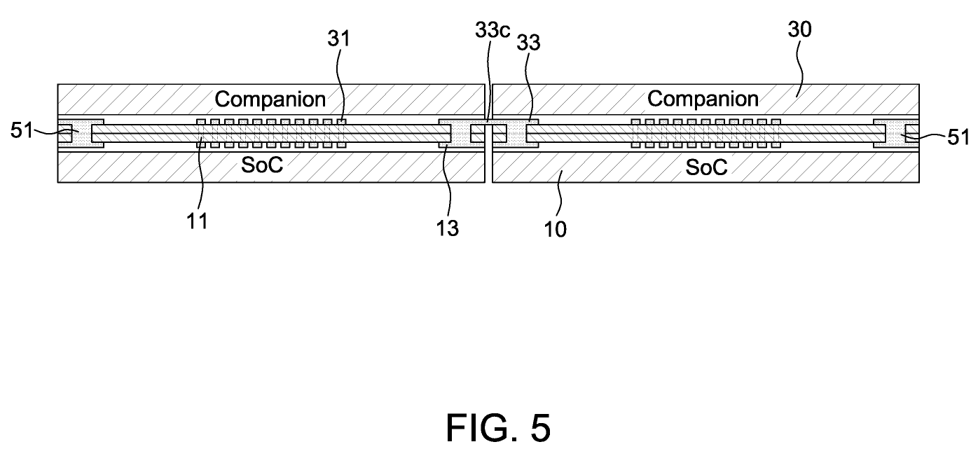

Please refer to FIG. 5, in the present disclosure, each of the SoC dies 100 is bonded to one of the companion dies 300/300’ (300 being shown as an example) through bonds on bond pads 11 and 31 and longitudinal vias 51 to cause one of the SoC dies 100 to communicate with another one (adjacent one, but not limited to) of the SoC dies 100 through the longitudinal vias 51 and the at least one inter-die connection 33c.

In the integrated circuit of the present disclosure, one of the SoC dies 100 communicates with another one of the SoC dies 100 not through the multiple bond pads 11 or the multiple bond pads 31; one of the SoC dies 100 communicates with another one of the SoC dies 100 through the first redistribution layer 13 and the second redistribution layer 33. In bonding the SoC die 100 to the companion die 300, the bonds 13v are aligned with the bonds 33v to form the longitudinal vias 51 to cause the first redistribution layer 13 to be electrically coupled with the second redistribution layer 33.

In the present disclosure, the second redistribution layer 33 of the companion dies 300 is not connected to any circuit inside the companion dies 300. That is, the inter-die connections 33c are not used to transmit signals from companion cells in one companion die 300 to companion cells in another companion die 300.

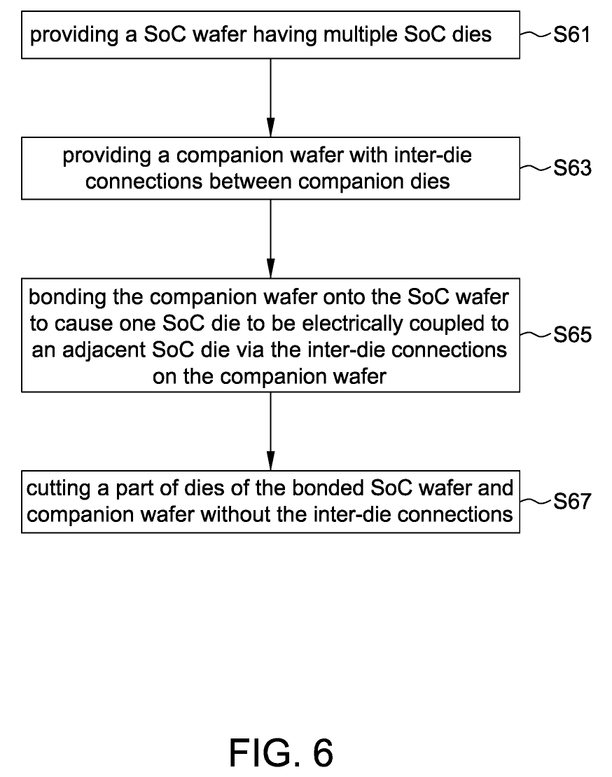

Please refer to FIG. 6, it is a flow chat of a method for manufacturing a 3D semiconductor integrated circuit according to one embodiment of the present disclosure. The method includes the steps of: providing an SoC wafer having multiple SoC dies (Step S61); providing a companion wafer having multiple companion dies and inter-die connections between the multiple companion dies (Step S63); bonding the companion wafer onto the SoC wafer to cause one SoC die on the SoC wafer to be electrically coupled to an adjacent SoC die via the inter-die connections on the companion wafer (Step S65); and cutting a part of dies of the bonded SoC wafer and companion wafer without the inter-die connections (Step S67).

Step S61: Please refer to FIG. 7, each of the SoC dies 71 (identical to 100 in FIGS. 1-2) includes transmitting and receiving circuits therein for communicating with adjacent SoC die 71s. Other microelectronic devices included in each SoC die 71 are determined according to an application of the 3D semiconductor integrated circuit. The SoC wafer 700 includes a first redistribution layer 73 (identical to 13 in FIGS. 1-2) formed on the multiple SoC dies 71, and the first redistribution layer 73 includes bonds 13v, which are formed by photolithography processes. The method of forming bonds penetrating through non-conductive layer (e.g., 153) is known to the art and thus details thereof are not described herein.

Step S63: Please refer to FIG. 8, each of the companion dies 81 (identical to 300 in FIGS. 3-4) includes circuits therein. The structure of a companion die is not particularly limited herein. The companion wafer 800 includes inter-die connections 83 (identical to 33c in FIGS. 4-5) between the multiple companion dies 81 formed by RDLs. As mentioned above, the inter-die connections 83 are not connected to the circuits inside the companion dies 81. The companion wafer 800 includes a second redistribution layer 83 (identical to 33 in FIGS. 3-4) formed on the multiple companion dies 81, and the second redistribution layer 83 includes bonds 33v, which are formed by photolithography processes.

Step S65: After bonding the SoC wafer 700 with the companion wafer 800, each SoC die 71 is aligned with one companion die 81 such that adjacent SoC dies 71 of the SoC wafer 700 are electrically coupled to each other via the inter-die connections 83 on the companion wafer 800. The bonds 13v are aligned with the bonds 33v to form longitudinal vias 51 (referred to FIG. 5) connected to the inter-die connections 83 (i.e. 33c in FIG. 5) such that the first redistribution layer 73 is electrically coupled with the second redistribution layer 83 through the longitudinal vias 51, which are formed by hybrid bonding.

Since the inter-die connections 83 are used as communication channels between two or more SoC dies 71, the inter-die connections 83 are preferably electrically coupled to at least the transmitting circuits and receiving circuits of the SoC dies 71.

Step S67: Finally, a cutting machine is used to cut off a part of dies of the bonded SoC wafer and companion wafer without the inter-die connections, e.g., SoC dies 71c shown by thinner lines in FIG. 7 and companion dies 81c shown by thinner lines in FIG. 8. After the dies 71c and 81c are cut off, the remained inter-die connected dies form the 3D semiconductor integrated circuit of the present disclosure, which may then be packaged and arranged on a circuit boarded/film according to applications thereof.

It is appreciated that the bonded SoC wafer and companion wafer further includes input/out connections (or fanouts) to interact with devices external to the 3D semiconductor integrated device of the present disclosure.

Please refer to FIGS. 3A-3C, in one aspect, a companion die provided by a vendor (e.g., FIG. 3A) is further processed to form the companion die 300 of the present disclosure. For example, a third part further processes a companion die with bond pads 31 in FIG. 3A to form conductive wires (as redistribution layer 33 in FIG. 3) perpendicular to edges of a companion die as the inter-die connections, referring to FIG. 3B. Next, bonds 33v on the conductive wires are formed using a photolithography system, e.g., including forming non-conductive layer, using masking and etching processes to remove a part of the non-conductive layer to form the bonds 33v, referring to FIG. 3C. In another aspect, it is possible that the vendor directly provides a companion wafer 300 including multiple companion dies 300 as shown in FIG. 3C.

In the present disclosure, the SoC wafer 700 and the companion wafer 800 may be manufactured separately and then bonded together using wafer-on-wafer (WoW) manufacturing process.

It should be mentioned that a number of and positions of dies capable of performing inter-die communication as well as a number of and positions of conductive wires shown in FIGS. 7-8 of the present disclosure are only intended to illustrate but not to limit the present disclosure. That is, a shape of the bonded SoC wafer and companion wafer is not limited to a rectangular shape as shown in FIGS. 7-8.

It should be mentioned that a part of the wafers 700 and 800 may be used to manufacture dies without inter-die connections, and another part of the wafers 700 and 800 may be used to manufacture dies with inter-die connections as mentioned herein.

In the present disclosure, a longitudinal direction is referred to a stacking direction of wafers/dies, and a transverse direction is referred to a direction parallel to a top surface of the wafers/dies.

In the present disclosure, the substrate is preferably formed of a silicon material (e.g., pure silicon), but may be additionally or alternatively formed of any suitable known material without particular limitations.

As mentioned above, the artificial intelligence requires extremely large data sets in a training stage and the 3D SoC can meet the requirements of high integration and speed. Accordingly, the present disclosure further provides a 3D semiconductor integrated circuit (e.g., FIG. 5) and a method for manufacturing the 3D semiconductor integrated circuit (e.g., FIG. 6) in which adjacent SoC dies in an SoC wafer communicate with each other through inter-die connections between companion dies in a companion wafer. In the present disclosure, adjacent companion dies do not communicate with each other through the inter-die connections. The inter-die connections are only for the communications between dies in another wafer. That is, communication signals of a first SoC die go out of the first SoC die to a first companion die stacked on the first SoC die, then the communication signals go to a second companion die adjacent to the first companion die, and finally the communication signals go to a second SoC die adjacent to the first SoC die from the second companion die stacked on the second SoC die.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A three-dimensional (3D) semiconductor integrated circuit, comprising:
two system-on-chip (SoC) dies, adjacent to each other; and
two companion dies, adjacent to each other and provided with at least one inter-die connection therebetween, wherein
each of the two SoC dies is bonded to each of the two companion dies through hybrid bond to cause one of the two SoC dies to communicate with the other one of the two SoC dies through the hybrid bond and the at least one inter-die connection.

2. The 3D semiconductor integrated circuit as claimed in claim 1, wherein
each of the two SoC dies comprises multiple first bond pads,
each of the two companion dies comprises multiple second bond pads, and
the one of the two SoC dies is configured to communicate with the other one of the two SoC dies not through the multiple first bond pads or the multiple second bond pads.

3. The 3D semiconductor integrated circuit as claimed in claim 1, wherein
each of the two SoC dies comprises a first redistribution layer,
each of the two companion dies comprises a second redistribution layer configured as the at least one inter-die connection, and
the one of the two SoC dies is configured to communicate with the other one of the two SoC dies through the first redistribution layer and the second redistribution layer.

4. The 3D semiconductor integrated circuit as claimed in claim 3, wherein the second redistribution layer of the two companion dies is not connected to any circuit in the two companion dies.

5. The 3D semiconductor integrated circuit as claimed in claim 3, wherein the first redistribution layer of the two SoC dies is connected to transmitting and receiving circuits in the two SoC dies.

6. The 3D semiconductor integrated circuit as claimed in claim 3, wherein
the first redistribution layer is covered by a first non-conductive layer with a first bond,
the second redistribution layer is covered by a second non-conductive layer with a second bond, and
the first bond is aligned with the second bond configured as longitudinal vias to cause the first redistribution layer to be electrically coupled with the second redistribution layer.

7. The 3D semiconductor integrated circuit as claimed in claim 3, wherein
the first redistribution layer comprises at least one conductive wire extending perpendicularly to an edge of each SoC die, and
the second redistribution layer comprises at least one conductive wire extending perpendicularly out of an edge of each companion die.

8. A 3D semiconductor integrated circuit, comprising:
an SoC wafer, comprising multiple SoC dies; and
a companion wafer, comprising multiple companion dies with inter-die connections between the multiple companion dies, wherein
the companion wafer is bonded onto the SoC wafer to cause adjacent SoC dies of the SoC wafer to be electrically coupled to each other via the inter-die connections on the companion wafer.

9. The 3D semiconductor integrated circuit as claimed in claim 8, wherein the inter-die connections are arranged perpendicular to edges of the multiple companion dies.

10. The 3D semiconductor integrated circuit as claimed in claim 8, wherein
each of the companion dies comprises circuits therein, and
the inter-die connections are not connected to the circuits.

11. The 3D semiconductor integrated circuit as claimed in claim 8, wherein
each of the SoC dies comprises transmitting and receiving circuits, and
the inter-die connections are electrically coupled to the transmitting and receiving circuits of the SoC dies.

12. The 3D semiconductor integrated circuit as claimed in claim 8, wherein
the SoC wafer further comprises a first redistribution layer formed on the multiple SoC dies, and the first redistribution layer comprises a first bond,
the companion wafer further comprises a second redistribution layer formed on the multiple companion dies, and the second redistribution layer comprises a second bond, and
the first bond is aligned with the second bond to cause the first redistribution layer to be electrically coupled with the second redistribution layer.

13. The 3D semiconductor integrated circuit as claimed in claim 12, wherein the first bond and the second bond form a longitudinal via connected to the inter-die connections.

14. A method for manufacturing a 3D semiconductor integrated circuit, comprising:
providing an SoC wafer having multiple SoC dies;
providing a companion wafer having multiple companion dies and inter-die connections between the multiple companion dies; and
bonding the companion wafer onto the SoC wafer to cause one SoC die on the SoC wafer to electrically coupled to an adjacent SoC die via the inter-die connections on the companion wafer.

15. The method as claimed in claim 14, wherein the inter-die connections are not electrically coupled to circuits in the companion dies.

16. The method as claimed in claim 14, wherein the providing the companion wafer further comprises:
forming conductive wires perpendicular to edges of the companion dies as the inter-die connections; and
forming bonds on the conductive wires using a photolithography system.

17. The method as claimed in claim 14, further comprising:
cutting a part of dies of the bonded SoC wafer and companion wafer without the inter-die connections.
